(19) United States
(12) Patent Application Publication
(10) Pub. No.: US 2011/0101406 A1
(43) Pub. Date: May 5, 2011

(54) Light emitting device package and method for manufacturing the same

(75) Inventors: Cheol Ho Heo, Busan-si (KR); Dek Gin Yang, Cheongwon-gun (KR); Myung Gun Chong, Changwon-si (KR)

(73) Assignee: Samsung Electro-Mechanics Co., Ltd., Suwon (KR)

(21) Appl. No.: 12/654,750

(22) Filed: Dec. 30, 2009

(30) Foreign Application Priority Data
Oct. 29, 2009 (KR) 10-2009-0103318

(51) Int. Cl. H01L 33/00; H01L 21/50

(52) U.S. Cl. 257/99; 438/26; 257/E33.056; 257/E33.066; 257/E21.499

(57) ABSTRACT

The present invention provides a light emitting device package including: a light emitting device structure having a light emitting device and a lead frame connected to the light emitting device; and a heat radiating structure bonded to the light emitting device structure and radiating heat generated from the light emitting device, wherein the heat radiating structure includes a conductive substrate, an insulating pattern covering a front surface of the conductive substrate opposite to the light emitting device structure, and a metal pattern bonded to the conductive substrate and the lead frame.

### CROSS-REFERENCE TO RELATED APPLICATIONS

This application claims the benefit of Korean Patent Application No. 10-2009-0103318 filed with the Korea Intellectual Property Office on Oct. 29, 2009, the disclosure of which is incorporated herein by reference.

### BACKGROUND OF THE INVENTION

1. Field of the Invention

The present invention relates to a light emitting device package and a method for manufacturing the same, and more particularly, to a light emitting device package having improved heat radiating efficiency, and a method for manufacturing the same.

2. Description of the Related Art

In general, a light emitting device package is formed by packaging a light emitting device such as a light emitting diode (LED) and light emitting laser to provide the light emitting device in home appliances, remote controllers, electronic displays, indicators, automation equipment, lighting equipment, and so on. Recently, as the light emitting device has been applied to various fields, packaging technology for effectively treating heat generated from the light emitting device during operation of the light emitting device is required. Especially, in case of the high output LED applied to the lighting equipment, since it generates high temperature heat due to increase of power consumption, it is required to improve heat radiating efficiency of the light emitting device. Currently, heat radiation treatment of the LED is performed by radiating heat generated from the LED to the outside through a ceramic substrate used for mounting the LED. However, in this case, cost of the light emitting element package is increased due to a high price of the ceramic substrate.

### SUMMARY OF THE INVENTION

The present invention has been proposed in order to solve the above-described problems, and it is, therefore, an object of the present invention to provide a light emitting device package having improved heat radiating efficiency.

Further, another object of the present invention is to provide a method for manufacturing a light emitting device package having improved heat radiating efficiency.

In accordance with an aspect of the present invention to achieve the object, there is provided a light emitting device package including: a light emitting device structure having a light emitting device and a lead frame connected to the light emitting device; and a heat radiating structure bonded to the light emitting device structure and radiating heat generated from the light emitting device, wherein the heat radiating structure includes a conductive substrate, an insulating pattern covering a front surface of the conductive substrate opposite to the light emitting device structure, and a metal pattern bonded to the conductive substrate and the lead frame.

In accordance with an embodiment of the present invention, the metal pattern may include at least one heat transmission via directly bonded to the conductive substrate through the insulating pattern.

In accordance with an embodiment of the present invention, the metal pattern may include at least one heat transmission line bonded to the conductive substrate through the insulating pattern.

In accordance with an embodiment of the present invention, the heat transmission line may have a ring-shaped cross section.

In accordance with an embodiment of the present invention, the metal pattern may be used as a circuit line for transmitting an electrical signal to the light emitting device and as a heat conductor for transmitting the heat generated from the light emitting device to the conductive substrate.

In accordance with an embodiment of the present invention, the insulating pattern may include a pre-preg layer.

In accordance with an embodiment of the present invention, a metal oxide film may be formed on the front surface of the conductive substrate to be bonded to the insulating pattern and the metal pattern.

In accordance with an embodiment of the present invention, the conductive substrate may be made of an aluminum material, and the metal oxide film may be an aluminum oxide film.

In accordance with another aspect of the present invention to achieve the object, there is provided a method for manufacturing a light emitting device package including the steps of: preparing a conductive substrate; sequentially forming an insulating film and a metal film on a front surface of the conductive substrate; forming a via hole in the metal film and the insulating film to expose the conductive substrate; forming a heat transmission via in the via hole; and coupling a light emitting device structure to a resulting structure in which the heat transmission via is formed.

In accordance with an embodiment of the present invention, the step of forming the heat transmission via may include the step of performing a plating process on a resulting structure in which the via hole is formed.

In accordance with an embodiment of the present invention, before forming the insulating film, the method may further include the step of forming a metal oxide film on the front surface of the conductive substrate, wherein the heat transmission via may be formed to be bonded to the metal oxide film.

In accordance with an embodiment of the present invention, the step of forming the heat transmission via may be performed by forming the same metal material as the metal film in the via hole.

In accordance with an embodiment of the present invention, the step of coupling the light emitting device structure to the resulting structure in which the heat transmission via is formed may include the step of bonding a lead frame of the light emitting device structure to the metal film.

In accordance with an embodiment of the present invention, the step of forming the metal oxide film may be performed by anodizing the conductive substrate.

In accordance with an embodiment of the present invention, the step of forming the metal oxide film may be performed by forming an aluminum oxide film on the front surface of the conductive substrate opposite to the light emitting device structure.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view showing a light emitting device package in accordance with an embodiment of the present invention;

FIG. 2 is a cross-sectional view taken along a line I-I′ shown in FIG. 1;

FIG. 3 is a view showing one modified example of a light emitting device package in accordance with an embodiment of the present invention;

FIG. 4 is a cross-sectional view taken along a line II-II′ shown in FIG. 3;

FIG. 5 is a view showing another modified example of a light emitting device package in accordance with an embodiment of the present invention;

FIG. 6 is a cross-sectional view taken along a line III-III′ shown in FIG. 5;

FIG. 7 is a flow chart showing a method for manufacturing a light emitting device package in accordance with an embodiment of the present invention; and

FIGS. 8 to 11 are views for describing a manufacturing process of a light emitting device package in accordance with an embodiment of the present invention.

### DETAILED DESCRIPTION OF THE PREFERRED EMBODIMENTS

The advantages and characteristics of the present invention and methods of achieving them will be apparent with reference to the following embodiments described in detail in conjunction with the accompanying drawings. However, the present invention is not limited to the following embodiments but may be embodied in various other forms. The embodiments are provided to complete the disclosure of the present invention and to completely inform a person with average knowledge in the art of the scope of the present invention. Like reference numerals refer to like elements throughout the present specification.

The terms used in the present specification are merely used to describe the embodiments and are not intended to limit the present invention. In the present specification, a singular form includes a plural form as long as not stated otherwise in related descriptions. The terms “comprise” and/or “comprising” do not exclude the existence or addition of one or more different components, steps, operations, and/or elements.

Hereinafter, a method for manufacturing a light emitting device package in accordance with an embodiment of the present invention will be described in detail with reference to the accompanying drawings.

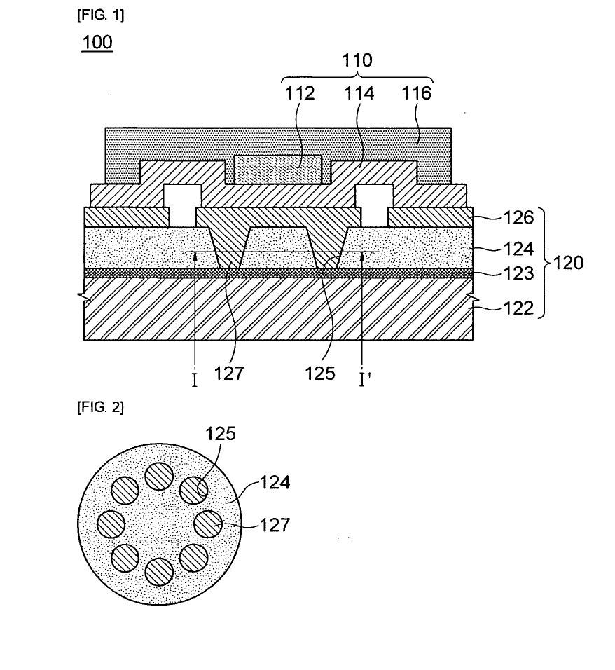

FIG. 1 is a view showing a light emitting device package in accordance with an embodiment of the present invention, and FIG. 2 is a cross-sectional view taken along a line I-I′ shown in FIG. 1. Referring to FIGS. 1 and 2, a light emitting device package 100 in accordance with an embodiment of the present invention includes a light emitting device structure 110 and a heat radiating structure 120, which are vertically bonded to each other.

The light emitting device structure 110 includes a light emitting device 112, a lead frame 114, and a molding film 116. The light emitting device 112 is at least one of a light emitting diode or a laser diode. As one example, the light emitting device 112 may be a light emitting diode. The lead frame 114 is bonded to a lower portion of the light emitting device 112. The lead frame 114 electrically connects the light emitting device 112 and the heat radiating structure 120. And, the molding film 116 covers the light emitting device 112 to protect the light emitting device 112 from external environment.

The heat radiating structure 120 radiates heat generated from the light emitting device 112. In addition, the heat radiating structure 120 is a package structure for mounting the light emitting device structure 110 to an external electronic device (not shown). The heat radiating structure 120 includes a conductive substrate 122, an insulating pattern 124, and a metal pattern 126. The conductive substrate 122 is a plate made of a conductive material having high thermal conductivity. For example, the conductive substrate 122 may be a metal substrate made of various kinds of metal materials. As one example, the conductive substrate 122 may be an aluminum (Al) substrate. A metal oxide film 123 is formed on a front surface of the conductive substrate 122 opposite to the light emitting device structure 110. The metal oxide film 123 may be an Al₂O₃ film. The insulating pattern 124 is formed to cover the front surface of the metal oxide film 123. In addition, the insulating pattern 124 has at least one via hole 125 which exposes the metal oxide film 123. The via hole 125 is disposed vertically opposite to the light emitting device 112. The insulating pattern 124 may be a pre-preg layer. And, the metal pattern 126 is formed to cover the via hole 125 and the insulating pattern 124. In addition, the metal pattern 126 is bonded to the lead frame 114 of the light emitting device structure 110. Accordingly, the metal pattern 126 has at least one heat transmission via 127 which is formed in the via hole 125 to be bonded to the lead frame 114 and the metal oxide film 123. Disposition of the heat transmission via 127 may be variously changed. For example, as shown in FIG. 2, in case that a plurality of heat transmission vias 127 are provided, the heat transmission vias 127 may be disposed at regular intervals with respect to a center of a region between the light emitting device 112 and the conductive substrate 122. Accordingly, the heat transmission vias 127 substantially form a ring shape. Since a heat transmission rate from the light emitting device 112 to the conductive substrate 122 is increased according to increase of an occupied area of the heat transmission vias 127, heat radiating efficiency of the light emitting device 112 can be improved. Meanwhile, the metal pattern 126 is made of a metal material having high thermal conductivity. As one example, the metal pattern 126 may be made of copper (Cu).

In the light emitting device package 100 in accordance with the above-described embodiment of the present invention, the heat generated from the light emitting device 112 is conducted to the conductive substrate 122 through the heat transmission via 127 of the metal pattern 126, and the conductive substrate 122 radiates the heat to the outside. At this time, some of the heat generated from the light emitting device 112 is radiated to the outside from the insulating pattern 124 through the conductive substrate 122. Accordingly, the light emitting device package 100 can improve the heat radiating efficiency of the light emitting device 112 by having the heat radiating structure 120 including the heat transmission via 127 which effectively conducts the heat of the light emitting device 112 to the conductive substrate 122.

Continuously, modified examples of a light emitting device package in accordance with an embodiment of the present invention will be described in detail. Here, a repeated description of the above-described light emitting device package will be omitted or simplified.

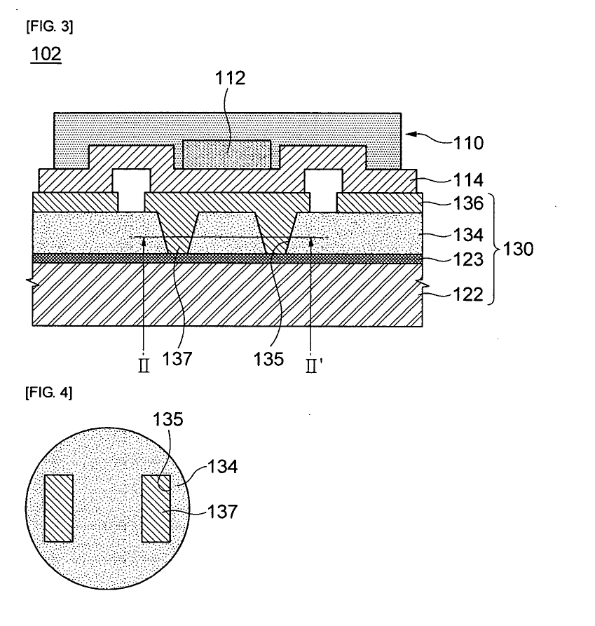

FIG. 3 is a view showing one modified example of a light emitting device package in accordance with an embodiment of the present invention, and FIG. 4 is a cross-sectional view taken along a line II-II′ shown in FIG. 3.

Referring to FIGS. 3 and 4, a light emitting device package 102 in accordance with one modified example of the present invention includes a light emitting device structure 110 and a heat radiating structure 130, which are vertically bonded to each other. The light emitting device structure 110 may be substantially the same as the above-described light emitting device structure 110, and a detailed description thereof will be omitted.

The heat radiating structure 130 includes a conductive substrate 122, an insulating pattern 134, and a metal pattern 136. The conductive substrate 122 may be an aluminum (Al) substrate. A metal oxide film 123, which is an aluminum oxide film, is formed on a front surface of the conductive substrate 122 opposite to the light emitting device structure 110. The insulating pattern 134 may be a pre-preg layer which covers a front surface of the metal oxide film 123. In addition, the insulating pattern 134 has at least one trench 135 which exposes the metal oxide film 123. The trench 135 has a long line shape in one direction. And, the metal pattern 136 is formed to cover the trench 135 and the insulating pattern 134. In addition, the metal pattern 136 is disposed to be bonded to a lead frame 114 of the light emitting device structure 110. Accordingly, the metal pattern 136 has at least one heat transmission line 137 which is formed in the trench 135 to be bonded to the lead frame 114 and the metal oxide film 123. The metal pattern 136 is made of a metal material having high thermal conductivity such as copper (Cu). The heat transmission line 137 may be variously disposed in a region between a light emitting device 112 and the conductive substrate 122. For example, in case that a plurality of heat transmission lines 137 are provided, the heat transmission lines 137 may be disposed at regular intervals in the region between the light emitting device 112 and the conductive substrate 122. In this case, heat transmission efficiency from the light emitting device 112 to the conductive substrate 122 is increased according to increase of an occupied area of the heat transmission lines 137.

The light emitting device package 102 in accordance with the above-described embodiment of the present invention has a structure in which heat generated from the light emitting device 112 is conducted to the conductive substrate 122 through the heat transmission line 137 of the metal pattern 136, and the conductive substrate 122 radiates the heat to the outside. Accordingly, the light emitting device package 102 can improve heat radiating efficiency of the light emitting device 112 by having the heat radiating structure 130 including the heat transmission line 137 which effectively conducts the heat of the light emitting device 112 to the conductive substrate 122.

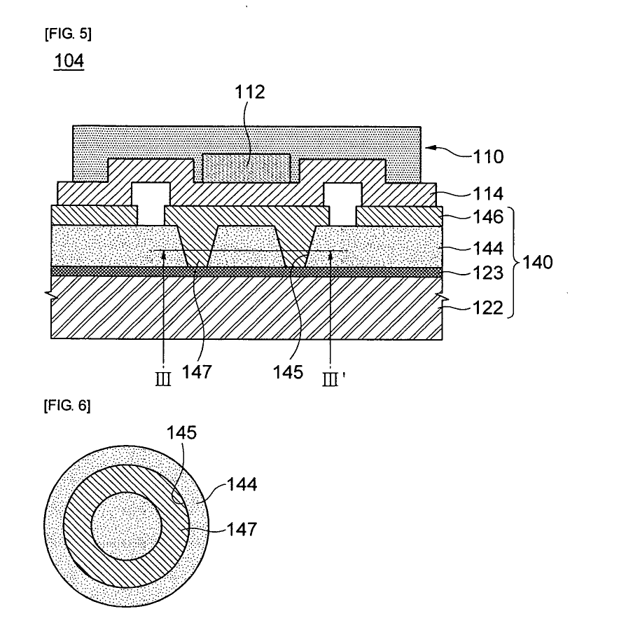

FIG. 5 is a view showing another modified example of a light emitting device package in accordance with an embodiment of the present invention, and FIG. 6 is a cross-sectional view taken along a line III-III′ shown in FIG. 5.

Referring to FIGS. 5 and 6, a light emitting device package 104 in accordance with another modified example of the present invention includes a light emitting device structure 110 and a heat radiating structure 140, which are vertically bonded to each other. The light emitting device structure 110 may be substantially the same as the above-described light emitting device structure 110, and a detailed description thereof will be omitted.

The heat radiating structure 140 includes a conductive substrate 122, an insulating pattern 144, and a metal pattern 146. The conductive substrate 122 may be an aluminum (Al) substrate. A metal oxide film 122, which is an aluminum oxide film, is formed on a front surface of the conductive substrate 122. The insulating pattern 144 may be a pre-preg layer which covers a front surface of the metal oxide film 123. In addition, the insulating pattern 144 has at least one depressed portion 145 which exposes the metal oxide film 123. The depressed portion 145 has a ring-shaped cross section. And, the metal pattern 146 is formed to cover the depressed portion 145 and the insulating pattern 144. In addition, the metal pattern 146 is disposed to be bonded to a lead frame 114 of the light emitting device structure 100. Accordingly, the metal pattern 146 has a ring-shaped heat transmission line 147 which is formed in the depressed portion 145 to be bonded to the lead frame 114 and the metal oxide film 123. The metal pattern 146 is made of a metal material having high thermal conductivity such as copper (Cu). The heat transmission line 147 has a ring shape with respect to a center of a region between a light emitting device 112 and the conductive substrate 122. Heat transmission efficiency from the light emitting device 112 to the conductive substrate 112 can be improved according to increase of an occupied area of the heat transmission line 147. Meanwhile, although the present embodiment describes an example in which one heat transmission line 147 is provided, the number, disposition, and shape of the heat transmission line 147 can be variously applied. For example, in case that a plurality of heat transmission lines 147 are provided, the respective heat transmission lines 147 may be concentric circles with respect to the center of the region between the light emitting device 112 and the conductive substrate 122. In this case, the heat transmission lines 147 form an annual ring. Or, in case that the plurality of heat transmission lines 147 are provided, the heat transmission lines 147 may be disposed in independent regions within the region between the light emitting device 112 and the conductive substrate 122.

The light emitting device package 104 in accordance with the above-described embodiment of the present invention has a structure in which heat generated from the light emitting device 112 is conducted to the conductive substrate 122 through the heat transmission line 147 of the metal pattern 146, and the conductive substrate 122 radiates the heat to the outside. Accordingly, the light emitting device package 104 can improve heat radiating efficiency of the light emitting device 112 by having the heat radiating structure 140 including the heat transmission line 147 which effectively conducts the heat of the light emitting device 112 to the conductive substrate 122.

Hereinafter, a manufacturing process of a light emitting device package in accordance with an embodiment will be described in detail. A repeated description of the above-described light emitting device package will be omitted or simplified. In addition, the following embodiment will describe a manufacturing process of a light emitting device package shown in FIG. 1, and a manufacturing process of a light emitting device package in accordance with modified examples of the present invention will be omitted.

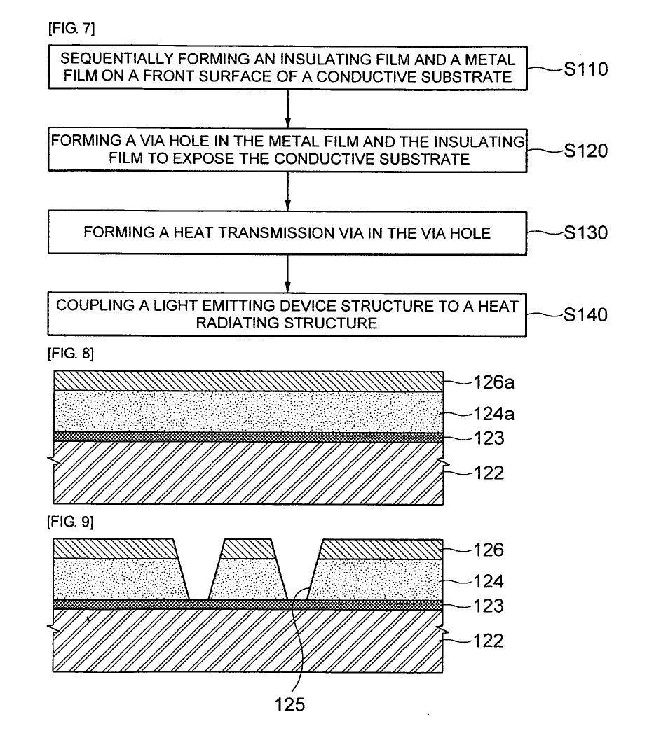

FIG. 7 is a flow chart showing a method for manufacturing a light emitting device package shown in FIG. 1, and FIGS. 8 to 11 are views for describing a manufacturing process of a light emitting device package in accordance with an embodiment of the present invention.

Referring to FIGS. 7 and 8, an insulating film 124a and a metal film 126a are sequentially formed on a front surface of a conductive substrate 122 (S110). For example, the conductive substrate 122 is prepared. The step of preparing the conductive substrate 122 includes the steps of preparing a metal plate and forming a metal oxide film 123 on a front surface of the metal plate. As one example, the step of preparing the conductive substrate 122 may include the steps of preparing an aluminum plate and forming an aluminum oxide film on a front surface of the aluminum plate. The step of forming the aluminum oxide film may be performed by anodizing the front surface of the metal plate. And, the step of forming the insulating film 124a includes the step of conformally forming a pre-preg layer on the metal oxide film 123. The step of forming the metal film 126a includes the step of conformally forming a copper film on the pre-preg layer. The step of forming the insulating film 124a is performed by pressing the pre-preg layer on the metal oxide film 123. Accordingly, it is possible to prevent separation of the insulating film 124a from the metal oxide film 123.

Referring to FIGS. 7 and 9, a via hole 125 is formed in the metal film 126a of FIG. 8 and the insulating film 124a of FIG. 8 to expose the conductive substrate 122 (S120). As one example, the step of forming the via hole 125 may be performed by a photoresist etching process on the metal film 126a and the insulating film 124a. As another example, the step of forming the via hole 125 may be performed by irradiating laser to the metal film 126a and the insulating film 124a or using a predetermined drill. Accordingly, an insulating pattern 124 and a metal pattern 126 having at least one via hole 125 exposing the metal oxide film 123 are formed on a front surface of the conductive substrate 122.

Referring to FIGS. 7 and 10, a heat transmission via 127 is formed in the via hole 125 (S130). As one example, a predetermined plating process may be performed on a structure in which the insulating pattern 124 and the metal pattern 126 are formed. The plating process may be one of an electroless plating process or an electroplating process. Accordingly, a metal via is formed in the via hole 125. As one example, the plating process may include a process of forming the metal via including copper (Cu) in the via hole 125. Accordingly, a heat radiating structure 120 having the heat transmission via 127 directly bonded to the metal oxide film 123 of the conductive substrate 122 is manufactured. After forming the heat transmission via 127, the step of forming a circuit line may be added by performing a predetermined patterning process on the metal pattern 126.

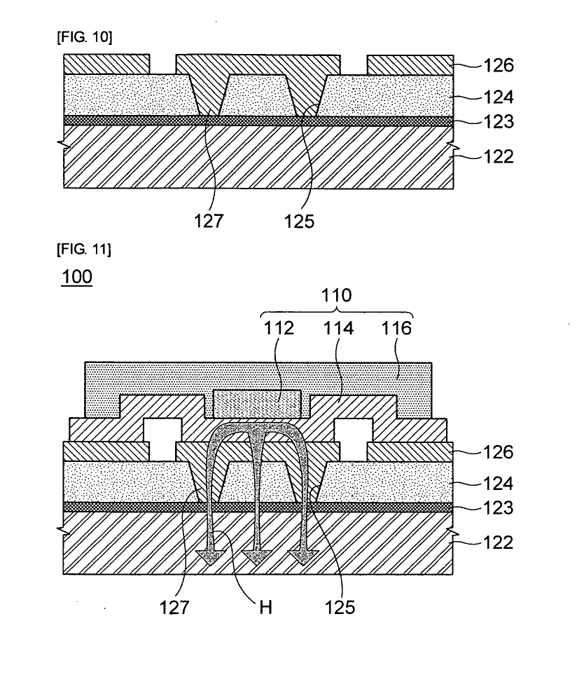

Referring to FIGS. 7 and 11, a light emitting device structure 110 is coupled to the heat radiating structure 120 (S140). For example, the light emitting device structure 110, which includes a light emitting device 112, a lead frame 114 provided in a lower portion of the light emitting device 112, and a molding film 116 covering the light emitting device 112, is prepared. And, the heat radiating structure 120 and the light emitting device structure 110 are bonded to each other so that the lead frame 114 of the light emitting device structure 110 is electrically connected to the metal pattern 126 of the heat radiating structure 120. Accordingly, the heat transmission via 127 formed in the metal pattern 126 is directly bonded to the lead frame 114 and the conductive substrate 122. The metal pattern 126 performs a function of transmitting heat H generated from the light emitting device 112 to the conductive substrate 122 and a function of a circuit line for transmitting an electrical signal to the light emitting device 112.

In accordance with the above-described embodiment of the present invention, it is possible to manufacture a light emitting device package 100 having a structure in which the heat H generated from the light emitting device 112 is conducted to the conductive substrate 122 through the heat transmission via 127 of the metal pattern 126, and the conductive substrate 122 radiates the heat H to the outside. Accordingly, the method for manufacturing the light emitting device package in accordance with the present invention can manufacture the light emitting device package 100 with improved heat radiating efficiency.

The light emitting device package in accordance with the present invention includes the metal pattern having the heat transmission via which is directly bonded to the lead frame of the light emitting device structure and the conductive substrate of the heat radiating structure. Accordingly, the heat radiating efficiency of the light emitting device package in accordance with the present invention is improved by effectively transmitting the heat generated from the light emitting device to the conductive substrate through the heat transmission via.

The method for manufacturing the light emitting device package in accordance with the present invention can manufacture the light emitting device package having the heat transmission via which is directly bonded to the lead frame of the light emitting device structure and the conductive substrate of the heat radiating structure. Accordingly, the method for manufacturing the light emitting device package in accordance with the present invention can manufacture the light emitting device package with the improved heat radiating efficiency by effectively transmitting the heat generated from the light emitting device to the conductive substrate through the heat transmission via.

The foregoing description illustrates the present invention. Additionally, the foregoing description shows and explains only the preferred embodiments of the present invention, but it is to be understood that the present invention is capable of use in various other combinations, modifications, and environments and is capable of changes and modifications within the scope of the inventive concept as expressed herein, commensurate with the above teachings and/or the skill or knowledge of the related art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments

1. A light emitting device package comprising:
a light emitting device structure having a light emitting device and a lead frame connected to the light emitting device; and
a heat radiating structure bonded to the light emitting device structure and radiating heat generated from the light emitting device, wherein the heat radiating structure includes;
a conductive substrate
an insulating pattern covering a front surface of the conductive substrate opposite to the light emitting device structure; and
a metal pattern bonded to the conductive substrate and the lead frame.

2. The light emitting device package according to claim 1, wherein the metal pattern includes at least one heat transmission via directly bonded to the conductive substrate through the insulating pattern.

3. The light emitting device package according to claim 1, wherein the metal pattern includes at least one heat transmission line bonded to the conductive substrate through the insulating pattern.

4. The light emitting device package according to claim 3, wherein the heat transmission line has a ring-shaped cross section.

5. The light emitting device package according to claim 1, wherein the metal pattern is used as a circuit line for transmitting an electrical signal to the light emitting device and as a heat conductor for transmitting the heat generated from the light emitting device to the conductive substrate.

6. The light emitting device package according to claim 1, wherein the insulating pattern includes a pre-preg layer.

7. The light emitting device package according to claim 1, wherein a metal oxide film is formed on the front surface of the conductive substrate to be bonded to the insulating pattern and the metal pattern.

8. The light emitting device package according to claim 1, wherein the conductive substrate is made of an aluminum material, and the metal oxide film is an aluminum oxide film.

9. A method for manufacturing a light emitting device comprising:
preparing a conductive substrate;
sequentially forming an insulating film and a metal film on a front surface of the conductive substrate;
forming a via hole in the metal film and the insulating film to expose the conductive substrate;
forming a heat transmission via in the via hole; and
coupling a light emitting device structure to a resulting structure in which the heat transmission via is formed.

10. The method according to claim 9, wherein forming the heat transmission via includes performing a plating process on a resulting structure in which the via hole is formed.

11. The method according to claim 9, before forming the insulating film, further comprising forming a metal oxide film on the front surface of the conductive substrate, wherein the heat transmission via is formed to be bonded to the metal oxide film.

12. The method according to claim 9, wherein forming the heat transmission via is performed by forming the same metal material as the metal film in the via hole.

13. The method according to claim 9, wherein coupling the light emitting device structure to the resulting structure in which the heat transmission via is formed includes the step of bonding a lead frame of the light emitting device structure to the metal film.

14. The method according to claim 9, wherein forming the metal oxide film is performed by anodizing the conductive substrate.

15. The method according to claim 14, wherein forming the metal oxide film is performed by forming an aluminum oxide film on the front surface of the conductive substrate opposite to the light emitting device structure.
